(19) United States
(12) Patent Application Publication
(10) Pub. No.: US 2025/0330171 A1
(43) Pub. Date: Oct. 23, 2025

(54) SWITCHED-CAPACITOR GATE DRIVER FOR DRIVING CAPACITIVE LOADS

(71) Applicant: The Trustees of Dartmouth College, Hanover, NH (US)

(72) Inventors: Yanqiao Li, Lebanon, NH (US); Jason T. Stauth, Hanover, NH (US); Ziyu Xia, Cupertino, CA (US)

(21) Appl. No.: 19/182,783

(22) Filed: Apr. 18, 2025

Related U.S. Application Data
(60) Provisional application No. 63/636,057, filed on Apr. 18, 2024.

(51) Int. Cl. H03K 17/16; H03K 17/08; H03K 17/284; H03K 19/0185

(52) U.S. Cl. CPC H03K 17/161; H03K 17/08; H03K 17/284; H03K 19/018507; H03K 2217/0081

(57) ABSTRACT

A circuit for driving a gate of a power semiconductor device includes multiple switching cells, each switching cell operable in a series-state and parallel-state and having an output coupled to a first terminal of an energy storage component, the output coupled through a first switching device to an input. A second switching device is coupled to a second terminal of the energy storage component and to the first input, and a third switching device is coupled to the second terminal of the energy storage component and to a different energy source or a second output of another of the plurality of switching cells. A controller generates control signals to switch the switching cells between a series-state and a parallel-state.

### CROSS REFERENCE TO RELATED APPLICATIONS

The present application claims priority to U.S. Provisional Patent Application No. 63/636,057, filed Apr. 18, 2024 and entitled “A Switched-Capacitor Gate Driver for Field Effect Transistors Achieving Power Reduction.” The entire contents of the aforementioned provisional patent application are incorporated herein by reference.

### STATEMENT REGARDING FEDERALLY SPONSORED RESEARCH OR DEVELOPMENT

This invention was made with government support under Grant No. 1822140, awarded by the Power Management Integration Center (PMIC), an Industry-University Cooperative Research Center (IUCRC) of the National Science Foundation. The government has certain rights in the invention.

### BACKGROUND

High voltage, high current, power semiconductor devices such as NMOS and PMOS power transistors, often formed of silicon or gallium nitride, are now common in many power handling systems, including inverters, electric cars, variable-frequency motor controllers, voltage converters, and many more. These transistors often require a gate-to-source voltage greater than the power supply voltages used for logic sections of many high-performance integrated circuits, including integrated circuits that control such high voltage, high current, NMOS and PMOS power transistors.

Typically, high power, high current, power transistors are mounted on heatsinks and may have several inches of wiring between them and circuitry that controls them. This wiring has parasitic inductance that may resonate with gate capacitance of the power transistors, in some systems this resonance is damped by adding resistance between the power transistor gates and the circuitry that controls the power transistors. In systems with conventional gate driving circuits this wiring/gate capacitance resonance may be underdamped giving significant voltage overshoot at the gate of the power transistors, and systems where this wiring/gate capacitance is overdamped may have slow voltage transitions on the power transistor gates-these slow voltage transitions can cause excessive power dissipation in the power transistors by keeping them in a saturation mode longer than necessary when switched from an off state to an on state, or vice versa. Overshoot at gates of power transistors is undesirable because it can result in potentially-damaging, momentary, overvoltage on those gates, or can produce conduction in gate protection circuitry on the power transistors.

Further, NMOS and PMOS power transistors frequently have significant gate capacitance. Traditional gate-driving circuits that switch power transistor gates between rails not only require a power supply providing an appropriate gate-source voltage for the gates but also expend significant power to switch the power transistor gate capacitances between rails. Such NMOS and PMOS power transistors often require significantly greater drive voltages than those used in much modern logic circuitry, for such power transistors the rails may be powered directly by a power supply or by a capacitive bootstrap circuit.

Capacitive charge-pump circuits were common in some generations of integrated circuits, including back-bias generators for NMOS integrated circuits. Most of these were configured as power supply circuitry and did not directly drive gates of high power, high current, power transistors, and most were single-stage designs.

### SUMMARY

The embodiments herein provide systems and methods for driving capacitive loads, such as but not limited to the gates of NMOS or PMOS power field-effect transistors. The embodiments operate from a supply voltage which may be provided by a power supply or through a dc-dc conversion circuit.

In an embodiment, the device has multiple switching cells, each switching cell of the plurality of switching cells has a capacitor and is operable in at least a series-state and parallel-state, the parallel-state using the power supply voltage to charge the capacitor, and the series-state coupling the charged capacitor to raise voltage on the load capacitance. The device also has a controller that generates, and where necessary level-shifts, control signals to configure each of the plurality of switching cells in either the series-state or the parallel-state in response to an input, an on-transition of the input causing controller to switch the switching cells to the series-state in a sequence resulting in the load capacitance stepwise reaching a high voltage greater than a power supply voltage, and an off-transitions of the input causing the controller to switch the switching cells to the parallel-state in a sequence resulting in reducing voltage at the load capacitance stepwise below the power supply voltage.

In an embodiment, a circuit for driving a gate of a power semiconductor device includes multiple switching cells, each switching cell operable in a series-state and parallel-state and having an output coupled to a first terminal of an energy storage component, the output coupled through a first switching device to an input. A second switching device is coupled to a second terminal of the energy storage component and to the first input, and a third switching device is coupled to the second terminal of the energy storage component and to a different energy source or a second output of another of the plurality of switching cells. A controller generates control signals to switch the switching cells between a series-state and a parallel-state.

### BRIEF DESCRIPTION OF THE DRAWINGS

FIG. 1A is a block level diagram of the switched-capacitor capacitive-load-driver circuit, in an embodiment.

FIG. 1B is a block-schematic diagram of a switched-capacitor capacitive-load-driver circuit that may have two, three, four, five, or more boost stages and may be used to drive a gate capacitance of an NMOS or PMOS power field-effect transistor.

FIG. 1C is a schematic diagram of a simplified switched-capacitor gate-driver circuit.

FIG. 1D is a schematic diagram of an alternative switched-capacitor gate-driver circuit where supply voltage to some or all switching cells may differ.

FIG. 2 incorporates a timing diagram showing responses to a ON transition and to an OFF transition of a control input to the driver of the present device.

FIG. 3 is a flowchart of a method of switching gate voltages at a large power transistor to turn the power transistor ON, then OFF, using the circuits herein described.

FIG. 4 illustrates an alternative “on” sequence where switching cells transition in an order other than the cell closest to the output first followed by the next nearest switching cell.

FIG. 5A illustrates how ringing on underdamped rising and falling edge transitions at the load can be controlled with the present design.

FIG. 5B illustrates a rising edge on an overdamped load with step transitions shown.

FIG. 6A is a schematic diagram of a simplified switched-capacitor gate-driver circuit similar to FIG. 1C with a simple digital timing sequencer and level shifter (TSLS).

FIG. 6B is a schematic diagram of a simplified switched-capacitor gate-driver circuit similar to FIG. 1C with a simple analog timing sequencer and level shifter.

FIG. 7 is a schematic diagram of an exemplary level shifter that may be used in the device.

### DETAILED DESCRIPTION OF THE EMBODIMENTS

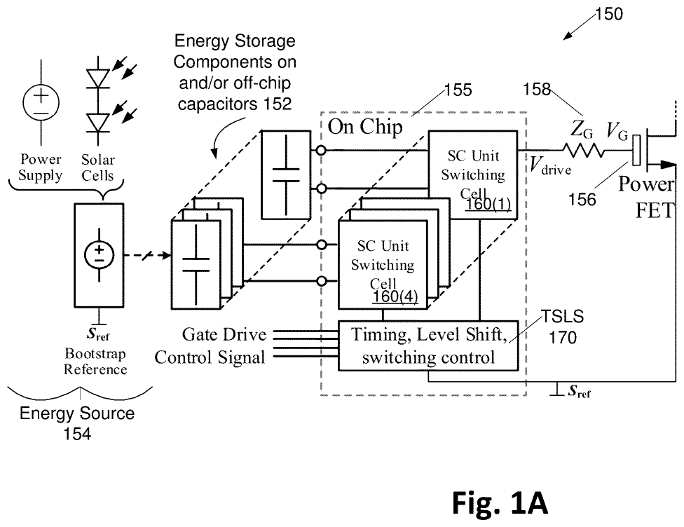

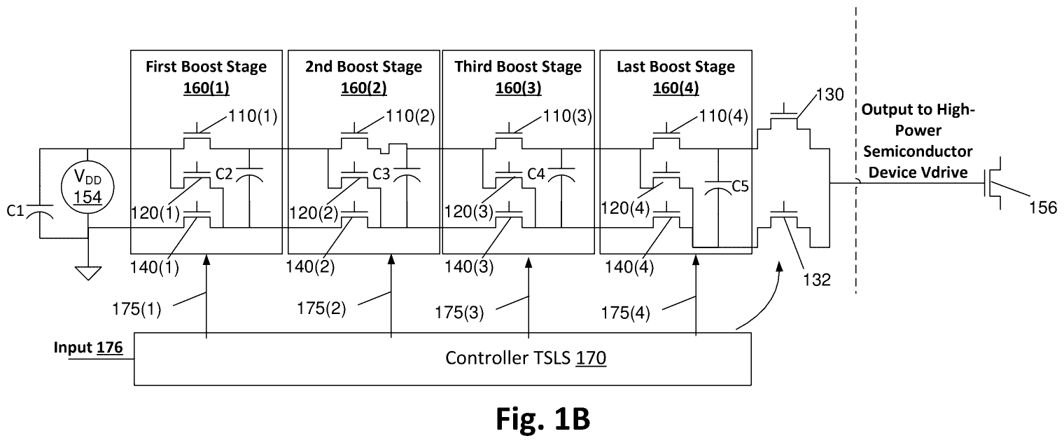

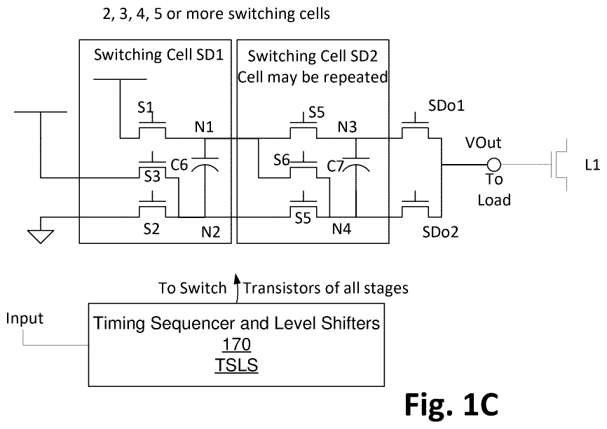

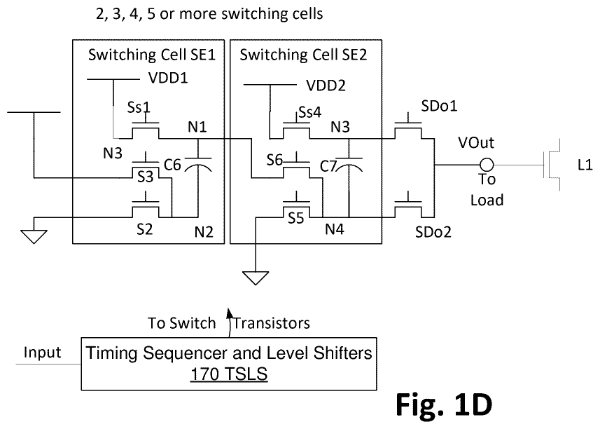

FIG. 1A is a block level diagram of the switched-capacitor capacitive-load-driver device 150, in an embodiment. FIG. 1B shows an example circuit diagram implementing the switched-capacitor capacitive-load-driver device 150. FIGS. 1A-B are best viewed together with the following description and features described in either may be interchangeable.

Switched-capacitor capacitive-load-driver device 150 is shown with at least one energy storage devices 152. There may be more or fewer multiple energy storage devices 152 than shown in FIG. 1A or FIG. 1B without departing from scope hereof. In one example, each energy storage devices 152 are capacitors in most embodiments and are coupled in series to drive a high signal into a capacitive load 156 after the energy storage devices are charged from an energy source 154. Energy source 154 may include a photovoltaic energy device, or may be another energy source such as a power supply or battery, and may include one or more voltage converters. In the embodiment shown in FIG. 1A, the capacitive load is typically an external power field-effect transistor (FET) 156. Device 150 also has on-chip logic 155 including a plurality of switching cells 160 and a timing sequencer with level shifters TSLS 170. Capacitive load 156 is driven through an impedance 158 that may generate ringing when load-driving signals transition under some conditions.

Each switching cell 160 shown in FIG. 1A may be implemented as one of a first boost stage 160(1), second boost stage 160(2), third boost stage 160(3), and last boost stage 160(4). There may be more or fewer boost stages than the four shown in FIG. 1A or 1B. The term “boost stage” and “switching cell” are interchangeable herein unless otherwise specified. Each of the plurality of switching cells (e.g., first boost stage 160(1), second boost stage 160(2), third boost stage 160 3), and last boost stage 160(4)), may include a capacitor and be operable in at least a series-state and parallel-state. First boost stage 160(1) is shown with capacitor C2, second boost stage 160(2) is shown with capacitor C3, third boost stage 160(3) is shown with capacitor C4, and last boost stage 160(4) is shown with capacitor C5. When in the parallel state the supply voltage V_{DD} charges the respective capacitor in each boost stage. When in the series-state the charged capacitor is coupled to the load to raise voltage on the load capacitance.

The device 150 also has a controller 170 TSLS that generates control signals 175(1)-(4) to respectively configure each of first boost stage 160(1), second boost stage 160(2), third boost stage 160(3), and last boost stage 160(4) in either the series-state or the parallel-state in response to an input signal 176. An on transition of input signal 176 causes controller 170 to switch control signals 175 to reconfigure each boost stage to the series-state in a sequence resulting in the load capacitance to rise from a first voltage to a second voltage, and an off-transition of the input signal 176 causes the controller 170 to switch control signals 175 to reconfigure each boost stage to the parallel-state in a sequence resulting in reducing voltage at the load capacitance below the second voltage to the first voltage as required to turn off power field-effect transistors such as FET 156.

The multiple switching cells act 160 in parallel-state to charge their respective capacitors C2, C3, C4, and C5 (FIG. 1B), and when all are in series-state act to string their capacitors in series, provide a voltage to drive the capacitive load 156, and when only some are in series-state provide a lesser voltage to drive the capacitive load 156.

To provide peak currents a power supply bypass capacitor C1 is shown. The energy storage components 152 of FIG. 1A are implemented as C2, C3, C4, and C5 in FIG. 1B. The energy source V_{DD}, which is an example of energy source 154 of FIG. 1A, may be one or more of a power supply, battery, or other source of energy such as photovoltaic cells and may be coupled to one or more of the energy storage components through switching transistors. In some embodiments, the energy source 154 includes a dc-dc conversion and may also provide higher voltages for use in level-shifting stages for driving gates switching transistors such as high-side charging or parallel transistors 110(1)-(4) and series transistors 120(1)-(4). Some low-side charging or parallel transistors 140(1)-(4) may also need level shifted gate drive. A pair of output control transistors 130, 132, are also provided and serve to provide a single output voltage step. To enter the parallel-state, each boost stage maybe configured with high side transistors 110(1)-(4) ON or conducting, and low-side transistors 140(1)-(4) ON. To enter the series-state, each boost stage may be configured with high side transistors 110(1)-(4) OFF or not conducting, low-side transistors 140(1)-(4) OFF, and series transistors 120(1)-(4) ON.

The switching cells 160 and timing controller 170, together with any needed level shifters, may be integrated in an integrated circuit (IC) or chip. The energy storage device 154 and associated components implemented as capacitors can be off-chip, on-chip or a combination of the two. The output of the multi-mode switched-capacitor gate driver (Vdrive) is connected to capacitive load 156 through an impedance (not shown in FIG. 1B) which may be a parasitic impedance and/or an intentionally added impedance.

The gate drive circuit is used to ‘turn on’ the power FET 156 by changing gate voltage VG to a level above a threshold voltage VTH (not shown) of the FET 156. This requires charging the capacitance presented by the FET at the gate VG, which may include capacitance between the gate-source and/or gate-drain of the device. Often the gate drive process is described as providing ‘gate charge’ to charge each portion of the gate capacitance to bring gate voltage VG above threshold voltage VTH.

There may be more than one energy source 154 and individual switching cells may charge each respective energy storage component 152 (e.g., capacitors C2-C5) to different voltages. Although in an embodiment all energy storage component capacitors are charged to a same voltage. Further, the energy storage component capacitors C2-C5 may be of different sizes as needed to produce a desired waveform at the load 156.

A simplified schematic diagram of the gate drive circuit is illustrated in FIG. 1C, where each switching cell SD1 or SD2 may represent one of switching cells 160 in FIG. 1A, or 1B. The driver has two, three, four, five, or more switching cells such as SD1 or SD2. In each switching cell SD1 there are at least three switching transistors, S1, S2, and S3. In each switching cell SD2 there are at least three switching transistors, S4, S5, and S6. S1 and S2 in switching cell SD1, and S5 and S4 in switching sell SD2 conduct when the respective switching cell is in parallel state and are off during series state; while S3 in switching cell SDI and S6 in switching sell SD2 conducts in series state but is off in parallel state. In parallel state, capacitor C6 of SD1 is charged to a supply voltage, with first terminal at node N1 coupled through switching transistor S1 driven to the supply voltage, while second terminal N2 remains coupled through switch S2 to a ground rail voltage. When switched to series state, C1's second terminal coupled to N2 is pulled to the voltage at N3, which is the supply voltage for a first switching cell SD1 but may be a different voltage for subsequent cells. Charge on capacitor C1 is then shared through an output of switching cell SC1 into the load capacitance or parasitic capacitance of any subsequent switching cells.

The load is coupled to a final switching cell SD2 through output switches SDo1 and SDo2. When a low output level is desired, low side switch SDo2 is ON, and high side switch SDo1 is OFF; when a higher output level is desired on the capacitive load, high side switch SDo1 is ON and low side switch SDo2 is OFF.

An alternative embodiment where switching cells need not share a single power supply connection is illustrated in FIG. 1D. In this embodiment, VDD1, a supply for switching cell SE1, and VDD2, a supply for switching cell SE2, may or may not be the same. SE1 and SE2 are examples of switching cells 160 of FIGS. 1A and 1B. Moreover, a given switched-capacitor capacitive-load-driver device 150 may have a plurality of switching cells 160 having at least one shared power supply (e.g., each “SD” in FIG. 1C, and a one or more of the plurality of switching cells 160 that have unshared power supplies (e.g., each “SE” in FIG. 1D). In this embodiment, it is necessary to turn off parallel-state charge transistors if switching other cells in some switching orders of the switching cells.

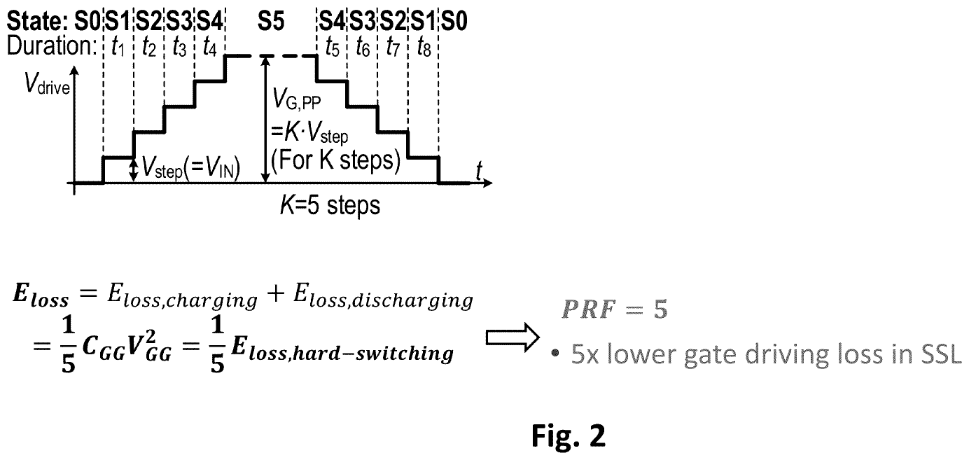

FIG. 2 illustrates operation of a driver with four stages of switching cells. The timing diagram illustrates a stepwise increase in an output voltage Vdrive of the driver which becomes the gate voltage of the driven device, and a stepwise decrease in the output voltage of the output voltage Vdrive as the driver turns off the driven semiconductor device as shown for a device with 4 capacitive boost stages and one set of output transistors as shown in FIG. 1B. Timing of the steps is independently controllable by the controller TSLS (FIG. 1A-D) in timesteps t1, t2, t3, t4 and t5, t6, t7 and t8. The output voltage is scalable according to how many boost stages are provided. FIG. 2 also illustrates that, because charge in each switching cell capacitor is not lost during switching of the gate driver and charge is placed on and then removed from the driven semiconductor device, the present driver recovers for reuse most of the energy required to switch the driven semiconductor device.

Switching transistors of the switching cells are controlled by a timing sequencer and level shifter unit 170 TSLS in response to a control input. To precharge the capacitors of each boost stage in FIG. 1C, in parallel state, the parallel switch transistor S1, S2, S5, and S6 are turned on with the series switch transistors S3 and S4 turned off or nonconducting.

To drive the load capacitance to a high level on receipt of an ON signal on the control input, switching transistor SDo1 is turned ON, after which there may be a short delay to allow current to pass through all S1's or S5's in all switching cells. Then switching cells SDI and SD2, and any other switching cells in the circuit, are turned to series state in a sequence. The switching cells are then turned from parallel state to series state in a predetermined order (which in some embodiments need not be sequential from right to left in FIG. 1B or FIG. 1C) across the chain of switching cells to cause voltage on the load L1 to increase in a sequence of multiple voltage steps. For example, if switching cell SD2 is turned to series state first with switch S4 conducting, as voltage on node N4 rises to match voltage on N2, charge on C7 is shared onto the load raising voltage at node N3. Then when switching cell SD1 is switched to its series state with switch S3 conducting, charge on C6 is shared into the total capacitance represented by C7 in series with load capacitance, raising voltage at node N3 even further. In some embodiments, switching of switching cells SD1 and SD2 may be simultaneous, and in others switching of switching cells is sequenced with delays between transition of switching cells to produce a stairstep waveform, as illustrated in FIG. 2 for the four-switching-cell implementation of FIG. 1B. The process is reversed on receiving an OFF signal on the control input, which may produce a falling stairstep waveform as the voltage on the load decreases in multiple steps.

Some of the energy delivered to the load gate to drive the load gate is recovered by capacitors C6, C7 from the load gate during falling transitions.

Timing of changes between parallel and series state of the individual cells is controlled by controller 170 TSLS. In embodiments, different cells, each of first boost stage 160(1), second boost stage 160(2), third boost stage 160(3), and last boost stage 160(4), transition between parallel and series state at different times during each rising and falling edge transition of the gate signal on load L1, which is an example of capacitive load 156. A duration of each voltage step, and a total duration of the of the multiple voltage steps of each transition is adjusted by design of the controller to mitigate ringing, including overshoot, on load L1 while switching drive on load L1 that sufficiently fast that undue power is not dissipated in load L1.

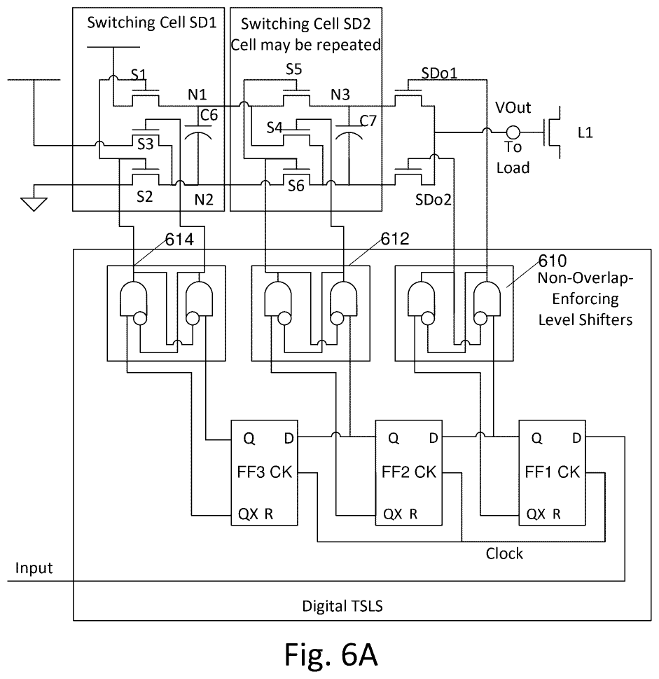

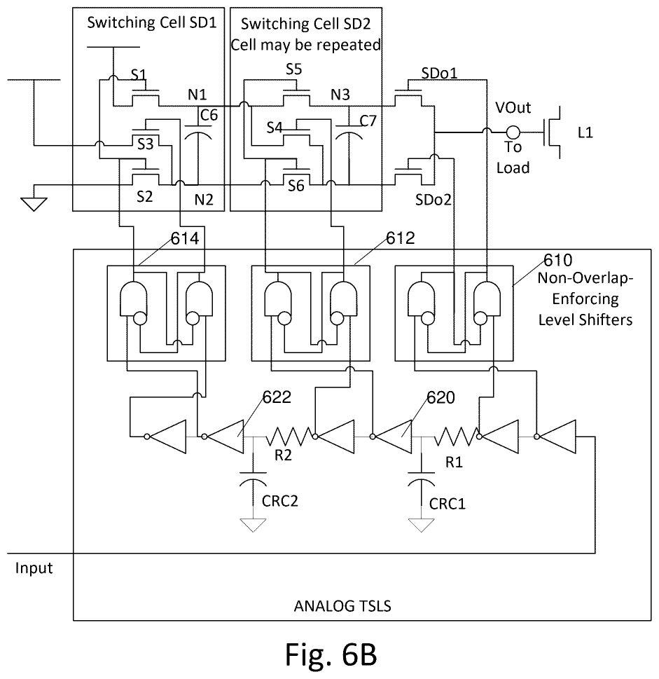

FIGS. 6A and 6B show non-limiting examples of controller 170. The controller TSLS may determine duration of each step digitally as illustrated in FIG. 6A using a shift register of D flipflops FF1, FF2, FF3 and non-overlap-enforcing level-shifters 610, 612, 614. Many variations of digital time delays are possible, in some embodiments digitally-determined time delays between steps are programmable, and in some embodiments a Gray-code counter and decoder is used for timing instead of a shift register. In an alternative embodiment, the controller TSLS may determine duration of each step using an analog circuit as illustrated in FIG. 6B.

In the analog TSLS embodiment of FIG. 6B, time duration of each step is determined by values of the resistors R1, R2, values of timing capacitors CRC1, CRC2, and thresholds of inverters 620, 622; values of these resistors and timing capacitors are chosen to minimize ringing and overshoot while optimizing gate signal risetime. Level-shifters 610, 612, 614 are provided as necessary to drive the switching transistors. Again, many variations of analog time delays are possible, for example multiple stages of R-C-Inverter may be used to determine each time step instead of the single R-C-Inverter stage shown in FIG. 6B.

The digital and analog TSLS designs illustrated in FIG. 6A and 6B may be expanded to any number of stages as required in a particular system and outputs of the time delay chains can be rearranged to switch the switching cells in any desired order as needed to obtain a desired piecewise-linear output waveform. Further, while switching devices are illustrated as positive-gate-to-source for ON NMOS transistors in the illustrated schematics, PMOS switching devices may replace illustrated switching devices in some embodiments, particularly in V_{DD}-side and series switching devices such as SDo1, Ss1, Ss5, S3, S4 of FIG. 1C and 1D, if gate signals are inverted as PMOS devices turn on with negative gate-to-source voltages; using PMOS switching devices may simplify the level shifting circuitry required to drive switching devices in some embodiments.

In a particular embodiment, not shown, duration of each step is controlled by analog circuits having a timing capacitor and controllable current source, time duration of each step being controllable by a gate voltage of the controllable current source thus permitting field adjustment of timing of one or more steps to minimize ringing and overshoot.

While positive outputs to capacitive loads are illustrated in the schematics provided herein, we note that positive or negative drive to capacitive loads are easily obtained, since the circuit can be built of PMOS transistors in place of NMOS transistors as switches and can be arranged to pump charge on the capacitive load L1 to high negative voltages as well as to high positive voltages.

In an alternative embodiment the energy storage devices 152 may be inductors.

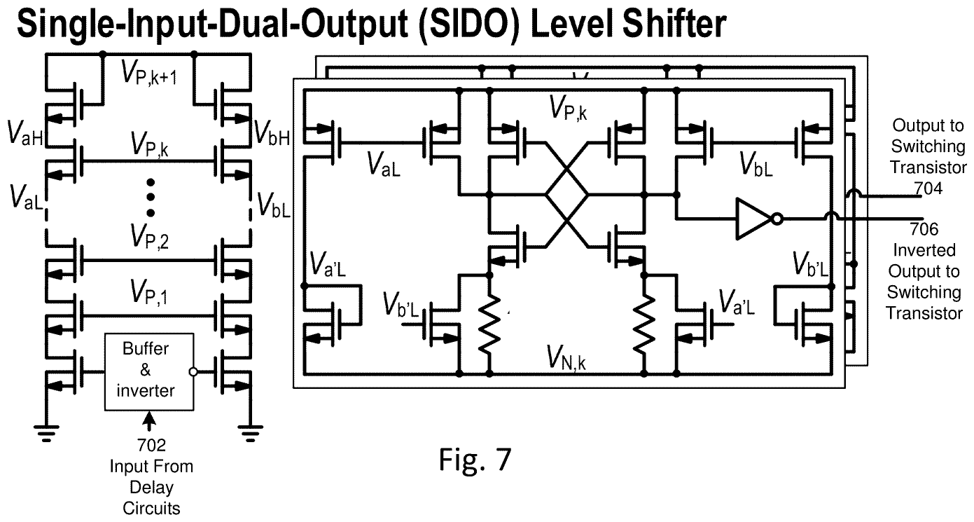

It may be necessary to level shift control signals from the analog delay line or the digital timing circuits of the TSLS before they can control the switch transistors such as 110 and 120 of FIG. 1A, 1B. One possible level shifter is shown in FIG. 7 having an input 702 and outputs 704, 706 to gates of switching transistors of the device. Other level shifters known in the art may also be used.

A method of driving a gate of a driven transistor includes providing a chain of capacitive boost stages, the chain of boost stages including at least a first and a last capacitive boost stage. Each capacitive boost stage has a first-input parallel switch transistor configured to controllably couple a first input to a first terminal of a capacitor, a second-input parallel switch transistor configured to controllably couple a second input to a second terminal of the capacitor, and a series transistor configured to controllably couple the second terminal of the capacitor to the first input; each capacitive boost stage has a parallel state with the first-input and second-input parallel switch transistors conducting and the series transistor nonconducting, and a series state with the first and second parallel switch transistor nonconducting and the series transistor conducting. A first output transistor couples the first terminal of the capacitor of the last boost stage to an output, the output configured to drive a gate of a driven transistor; while a second output transistor couples the second terminal of the capacitor of the last boost stage to the gate of the driven transistor.

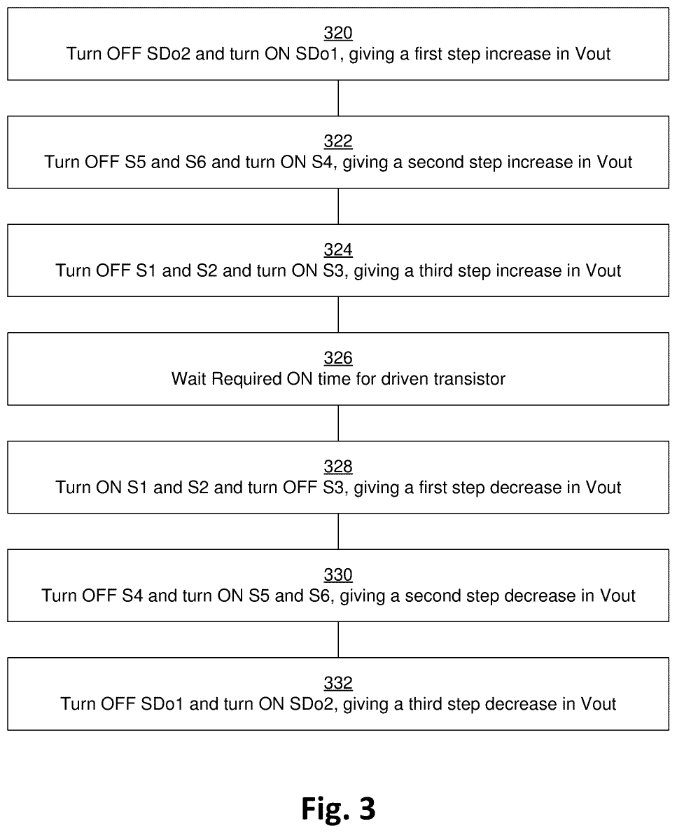

With reference to FIG. 3 and FIG. 1C, upon receiving an ON transition of a control input, the first output transistor SDo1 is turned ON and the second output transistor SDo2 is turned OFF 320, this gives a first step increase in voltage at VOut, and each of the capacitive boost stages are switched in a sequence to the series state by, for cell SD2 turning off S5 and S6, then turning on S4 giving another step increase in voltage at VOut 322. After cell SD2 is switched, cell SD1 is also switched turning off S1 and S2 and turning on S3 to give another step increase at VOut 324. The controller then waits 326 for the required on-time of the driven transistor, as indicated by an off transition of the control input. Upon receiving an off transition of the control input, each of the capacitive boost stages is switched in 328, 330 a sequence to the parallel state; cell SD1 by turning ON S1 and S2 and S3 off 328 and cell SD3 by turning on S5 and S6 while turning off S4 330; and then the second output transistor SDo2 is turned on and the first output transistor SDo1 is turned off 332 to end the stairstep.

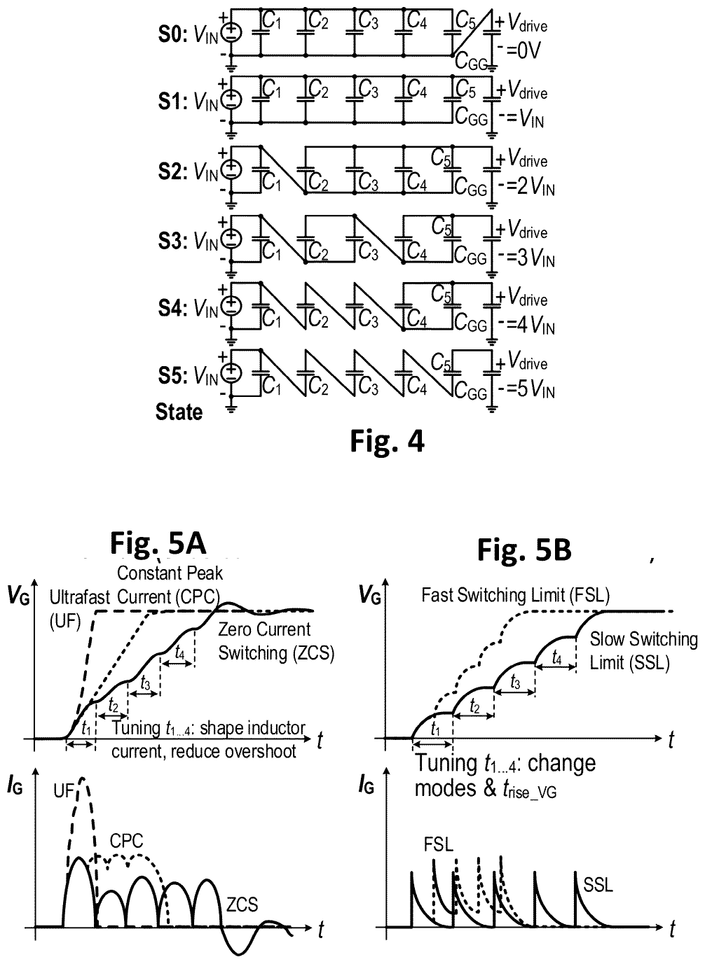

While the discussion above referencing switching of the embodiments of FIGS. 1C and 1D referred to switching the switching cell closest to the load first on rising transitions with the switching cell furthest from the load last; and the switching cell furthest from the load first and the cell closest to the load last for falling transitions, this switching sequence is not mandatory in embodiments with series connected parallel or charging transistors like S1 and S5 of FIG. 1C or transistors 110(1)-(4) of the embodiment of FIG. 1B. FIG. 4 illustrates an alternative switching sequence usable for rising transitions; several other switching sequences will produce similar transitions on the load.

When the present driver is used on an otherwise underdamped load, the stepwise transition tends to reduce ringing and overshoot as shown by voltage Vg in FIG. 5A. The timing between each step t1, t2, t3, t4, may be the same for all steps as shown, or may be different as required to provide a desired waveform at the load. This timing can be adjusted by adjusting the design of controller TSLS (FIG. 1B, 1C, 1D, 6A, 6B) as needed for a particular application. Ig illustrates current into the load.

FIG. 5B represents voltages and current when the present driver is used on an overdamped load.

Timing between steps can be adjusted to take advantage of resonant power transfer to the load.

Changes may be made in the above system, methods or device without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. A circuit for driving a gate of a power semiconductor device, comprising:
a plurality of switching cells, each switching cell of the plurality of switching cells operable in a series-state and parallel-state and comprising:
an output coupled to a first terminal of an energy storage component;
a first input coupled to a node selected from the output of another of the plurality of switching cells and an energy source,
at least one first switching device coupled between the output and the first input,
at least one second switching device coupled to a second terminal of the energy storage component and to the first input, and
at least one third switching device coupled to the second terminal of the energy storage component and to an energy source or a second output of another of the plurality of switching cells;
a controller that generates control signals to configure each of the plurality of switching cells in either the series-state or the parallel-state; and,
an output of a switching cell being configured to couple to the gate of the power switching device.

2. The circuit of claim 1, wherein the plurality of switching cells and the controller are components of a same chip.

3. The circuit of claim 2, a plurality of the energy storage components being on the same chip as the switching devices.

4. The circuit of claim 2, a plurality of the energy storage components being off-chip from the switching devices.

5. The circuit of claim 1, each energy storage component of the plurality of energy storage components being a capacitor.

6. The circuit of claim 5, wherein the control signals are sequenced by the controller to cause a voltage at the gate to increase or decrease in a plurality of voltage steps.

7. The circuit of claim 6, wherein a time duration of a transition on the gate is adjustable by the controller.

8. The circuit of claim 6, wherein a time duration of a transition on the gate is configured by the controller to mitigate one or both of ringing and overshoot of a voltage waveform at the gate.

9. The circuit of claim 5, the plurality of capacitors capable of delivering energy to the gate and to recover energy from the gate.

10. The circuit of claim 5, the switching devices of the plurality of switching cells configurable by the controller to couple the capacitors of the plurality of switching cells in either series or parallel to control voltage at the gate.

11. The circuit of claim 5 further comprising one or more energy sources either:
couplable in parallel with the plurality of energy storage devices; or
coupled to a connecting node of the plurality of energy storage devices.

12. A switched-capacitor driver powered by a first rail and a second rail, the switched-capacitor driver controllable by a control input, the driver comprising:
at least a first and a second capacitive boost stage, each capacitive boost stage comprising:
a first-parallel switch transistor configured to controllably charge a first terminal of a capacitor,
a second parallel switch transistor configured to controllably couple a second input to a second terminal of the capacitor, and
a series transistor configured to controllably couple the second terminal of the capacitor to a first input;
each capacitive boost stage having a parallel state with the first and second parallel switch transistor conducting and the series transistor nonconducting, and a series state with the first and second parallel switch transistor nonconducting and the series transistor conducting;
a first output transistor coupled to controllably couple the first terminal of the capacitor of the second capacitive boost stage to an output, the output configured to drive a gate of a power transistor;
a second output transistor coupled to controllably couple the second terminal of the capacitor of the second capacitive boost stage to the output;
a delay unit coupled to transition the first output transistor to an on state, transition the first capacitive boost stage from the parallel state to the series state, and transition the second capacitive boost stage from the parallel state to the series state, in a sequence beginning after receiving an on transition of the control input, the delay unit configured such that no two of the first output transistor, the first capacitive boost stage, and the second capacitive boost stage transition simultaneously;
wherein the first input of the first capacitive boost stage is coupled to the first rail, and the second input of the first capacitive boost stage is coupled to the second rail; and
the series transistor of the second capacitive boost stage is coupled to the first terminal of the capacitor of the first capacitive boost stage.

13. The switched-capacitor driver of claim 12, further comprising a third capacitive boost stage, the first output transistor being coupled to the first terminal of the capacitor of the second capacitive boost stage through the third capacitive boost stage, and the second output transistor being coupled to the second terminal of the capacitor of the second capacitive boost stage through the third capacitive boost stage;
where, upon an on transition of the control input, the delay unit is configured to transition the third capacitive boost stage from the parallel state to the series state at a time different from when the first capacitive boost stage transitions to the series state and different from when the second capacitive boost stage transitions to the series state.

14. The switched-capacitor driver of claim 13, the delay unit configured to, upon receiving an off transition of the control input, transition the second capacitive boost stage from the series state to the parallel state, then after a delay, transition the first capacitive boost stage from the series state to the parallel state, then after a delay, turn off the first output transistor and turn on the second output transistor.

15. The switched capacitor driver of claim 12, wherein the delay unit is digital.

16. The switched capacitor driver of claim 12 wherein the delay unit is analog.

17. A method of driving a gate of a driven transistor comprising:
providing a chain of capacitive boost stages, the chain of boost stages comprising at least a first and a last capacitive boost stage, each capacitive boost stage comprising:
a first-input parallel switch transistor configured to controllably couple a first input to a first terminal of a capacitor,
a second-input parallel switch transistor configured to controllably couple a second input to a second terminal of the capacitor, and
a series transistor configured to controllably couple the second terminal of the capacitor to the first input;
each capacitive boost stage having a parallel state with the first-input and second-input parallel switch transistors conducting and the series transistor nonconducting, and a series state with the first and second parallel switch transistor nonconducting and the series transistor conducting;
providing a first output transistor that couples the first terminal of the capacitor of the last boost stage to an output, the output configured to drive the gate of the driven transistor;
a second output transistor couples the second terminal of the capacitor of the last boost stage to the gate of the driven transistor;
upon receiving an on transition of a control input, in sequence performing:
turning on the first output transistor and turn off the second output transistor, and sequentially switching each of the capacitive boost stages to the series state; and
upon receiving an off transition of the control input, in sequence performing:
sequentially switching each of the capacitive boost stages to the parallel state; and
turning on the second output transistor and turning off the first output transistor.

18. The method of claim 17, wherein the chain of boost stages further comprises a third boost stage coupled between the first boost stage and the last boost stage, and wherein the method further comprises, upon receiving an on transition of the control input, after turning switching the last capacitive boost stage to the series state and before waiting for the second delay time:
after a third delay time, transitioning the third boost stage from the parallel state to the series state.

19. The method of claim 17, wherein the sequential switching of each of the capacitive boost stages is controlled in response to one pulse signal.
